(19) United States
(12) Patent Application Publication
(10) Pub. No.: US 2026/0066893 A1
(43) Pub. Date: Mar. 5, 2026

(54) CIRCUIT WITH COUNTERROTATIONAL CIRCUIT PATHS

(71) Applicant: Infineon Technologies Austria AG, Villach (AT)

(72) Inventors: Kangming XIONG, Chongqing (CN); Milko PAOLUCCI, Sattendorf (AT); Jin WANG, Shenzhen (CN); Kok Yau CHUA, Melaka (MY); Chee Yang NG, Muar (MY); Qingliang SONG, Shenzhen (CN)

(21) Appl. No.: 18/824,469

(22) Filed: Sep. 4, 2024

(51) Int. Cl. H03K 17/16

(52) U.S. Cl. CPC H03K 17/162

(57) ABSTRACT

A circuit that includes two current path circuits—a first current path circuit and a second current path circuit in which current flow is in opposite rotational directions in a current flow plane. If a same differential voltage is applied across the first current path circuit and the second current path circuit, this will induce relative counter rotational current in each current path circuit. This is true even if the first voltage and/or second voltage are changing. Accordingly, the counterflows at least partially cancel out electromagnetic interference across a range of frequencies.

### BACKGROUND

When a changing current flows through a conductor, a changing electromagnetic field is emitted from the conductor. Sometimes, the frequency and magnitude of the emitted electromagnetic field is such that the field can interfere with the proper functioning of surrounding circuitry. In this case, the emitted changing electromagnetic field may be referred to as electromagnetic interference, or EMI.

One method to control EMI is to at least partially surround the conductor with a shield that blocks much of the EMI from emitting external to the shield. Other methods involve adding a filter to filter out the interfering frequencies. As an example, that filter might be a circuit network that includes an inductor and capacitor—also called an “L-C circuit”. Yet another method involves changing the circuit itself so that it does not have changing current that is within the range of frequencies that could interfere with surrounding circuitry.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Embodiments described herein relate to a circuit that includes two current path circuits—a first current path circuit and a second current path circuit. The first current path circuit has a first voltage supply node and a second voltage supply node. The first current path circuit is structured such that when current flows from the first voltage supply node to the second voltage supply node, current flow through the first current path circuit is in a first rotational direction in a current flow plane. On the other hand, the second current path circuit has a third voltage supply node and a fourth voltage supply node. The second current path circuit is structured such that when current flows from the third voltage supply node to the fourth voltage supply node, current flow through the second current path circuit is in a second rotational direction in the current flow plane, the second rotational direction being opposite the first rotational direction in the current flow plane.

Accordingly, if a same first voltage is applied to the first voltage supply node and the third voltage supply node, and a same second voltage is applied to the second voltage supply node and the fourth voltage supply node, current would flow in different rotational directions in the first current path circuit as compared to the second current path circuit thereby attenuating electromagnetic interference. For instance, if current flows clockwise in the first current flow path circuit, current flows counterclockwise in the second current flow path circuit, and vice versa. This is true even if the first voltage and/or second voltage are changing. Accordingly, the counterflows at least partially cancel out electromagnetic interference across a range of frequencies.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates a circuit that represents just one example of a circuit consistent with the principles described herein, and which includes two current path circuits that have flow paths in opposite rotational directions so as to at least partially cancel electromagnetic interference;

FIG. 2 illustrates an example circuit that represents an example of FIG. 1, but in which the current path circuits are implemented using High Electron Mobility Transistors (HEMTs);

FIG. 3 illustrates an integrated circuit that includes an instance of the circuit of FIG. 2, and in which capacitors are formed on the same integrated circuit as the HEMTs;

FIG. 4 illustrates an integrated circuit that includes an instance of the circuit of FIG. 2, and in which capacitors are co-packaged with the integrated circuit that contains the HEMTs;

FIG. 5 illustrates an integrated circuit that includes an instance of the circuit of FIG. 2, and in which capacitors are on the same circuit board as a package that includes the integrated circuit that contains the HEMTs;

FIG. 6 illustrates an example circuit in which there are four transistors that may each be structured as described for the HEMTs of FIG. 2, and which may be used as part of a buck converter circuit;

FIG. 7 illustrates an example circuit in which there are four transistors that may each be structured as described for the HEMTs of FIG. 2, and which may be used as part of a bi-directional switch with the transistors in common-drain configuration;

FIG. 8A illustrates a circuit that represents a cascode configuration of an enhancement mode HEMT with a low voltage transistor to emulate a depletion mode HEMT;

FIG. 8B illustrates a circuit that represents a direct drive configuration of an enhancement mode HEMT with a low voltage transistor to emulate a depletion mode HEMT; and

FIG. 9 illustrates an embodiment of a buck converter circuit that is an extension of the circuit of FIG. 6, but in which the inductor capacitor network also has an additional set of counter-rotational flows used to at least partially cancel out EMI generated in the inductor capacitor network.

### DETAILED DESCRIPTION

Embodiments described herein relate to a circuit that includes two current path circuits—a first current path circuit and a second current path circuit. The first current path circuit has a first voltage supply node and a second voltage supply node. The first current path circuit is structured such that when current flows from the first voltage supply node to the second voltage supply node, current flow through the first current path circuit is in a first rotational direction in a current flow plane. On the other hand, the second current path circuit has a third voltage supply node and a fourth voltage supply node. The second current path circuit is structured such that when current flows from the third voltage supply node to the fourth voltage supply node, current flow through the second current path circuit is in a second rotational direction in the current flow plane, the second rotational direction being opposite the first rotational direction in the current flow plane.

Accordingly, if a same first voltage is applied to the first voltage supply node and the third voltage supply node, and a same second voltage is applied to the second voltage supply node and the fourth voltage supply node, current would flow in different rotational directions in the first current path circuit as compared to the second current path circuit thereby attenuating electromagnetic interference. For instance, if current flows clockwise in the first current flow path circuit, current flows counterclockwise in the second current flow path circuit, and vice versa. This is true even if the first voltage and/or second voltage are changing. Accordingly, the counterflows at least partially cancel out electromagnetic interference across a range of frequencies.

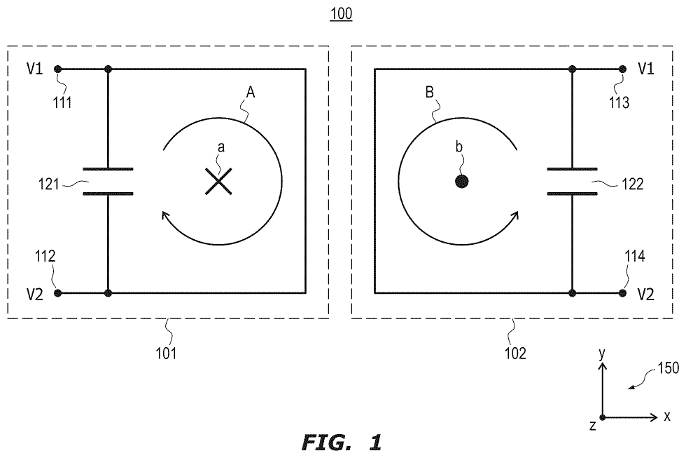

FIG. 1 illustrates a circuit 100 that represents just one example of a circuit consistent with the principles described herein. The circuit 100 includes a first current path circuit 101 and a second current path circuit 102. The first current path circuit 101 includes a first voltage supply node 111 and a second voltage supply node 112. The second current path circuit 102 includes a third voltage supply node 113 and a fourth voltage supply node 114.

The first current path circuit 101 is structured such that when current flows from the first voltage supply node 111 to the second voltage supply node 112, current flow through the first current path circuit 101 is in a first rotational direction A in a current flow plane. With reference to the coordinate system 150, the current flow plane is in the x-y plane. On the other hand, the second current path circuit 102 is structured such that when current flows from the third voltage supply node 113 to the fourth voltage supply node 114, current flow through the second current path circuit 102 is in a second rotational direction B in the current flow plane, the second rotational direction B being opposite the first rotational direction A in the current flow plane.

Accordingly, if a same first voltage (e.g., V1 in FIG. 1) is applied to the first voltage supply node 111 and the third voltage supply node 113, and if a same second voltage (e.g., V2 in FIG. 1) is applied to the second supply node 112 and the fourth supply node 114, current would flow in opposite rotational directions in the first current path circuit 101 as compared to the second current path circuit 102.

If the current flow in the first current path circuit 101 is clockwise as in the rotational direction A in FIG. 1, then this will cause an electromagnetic field a that will extend into the negative z-direction (referencing the coordinate system 150) within the circle of current flow. In this case, the current flow in the second current path circuit 102 is counterclockwise as in the rotational direction B in FIG. 1. Accordingly, this will cause an electromagnetic field b that will extend into the positive z-direction within the circle of current flow. The representation of the electromagnetic field resulting from current flow is simplified in FIG. 1. In reality, the electromagnetic fields will be quite complex and change over time. Nevertheless, the principle herein is that the counter-rotational current flows will generate electromagnetic fields that will at least partially cancel each other out at each instant of time.

If the first current path circuit 101 and the second current path circuit 102 are symmetrical in the x-direction, then the counter-rotational currents will largely mirror one another in magnitude and frequency. Furthermore, in the illustrated embodiment, though not required, the first current path circuit 101 includes capacitor 121 configured as shown with one of its terminals connected to the first voltage supply node 111 and the other terminal connected to the second voltage supply node 112. In addition, in that embodiment, the second current path circuit 102 includes capacitor 122 configured as shown with one of its terminals connected to the third voltage supply node 113 and the other terminal connected to the fourth voltage supply node 114. This allows for the rotational flow to be more complete, particularly for alternating current frequencies at which the capacitors provide little impedance. Thus, the capacitors 121 and 122 also provide a more complete mutual cancelation of the electromagnetic fields generated by the first current path circuit 101 and the second current path circuit 102.

Such would be the case across a wide range of frequencies of the differential voltage (V1 minus V2). This is because the first input voltage V1 is shared by the voltage supply nodes 111 and 113, and the second input voltage V2 is shared by the voltage supply nodes 112 and 114. Accordingly, the current flows (and resulting electromagnetic fields) have the same frequency spectrum, but are opposite in magnitude at any given time. Thus, the current flows in the first current path circuit 101 and the second current path circuit 102 will generate electromagnetic fields that, through destructive interference, are partially cancelled out across a wide range of frequencies of the differential voltage.

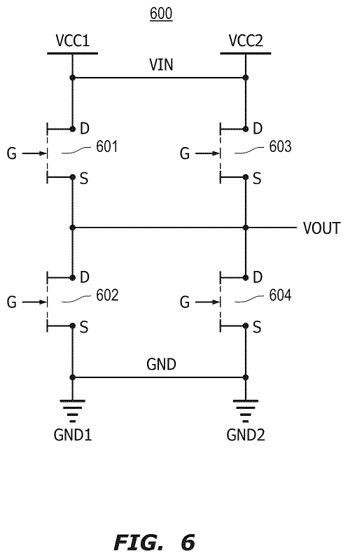

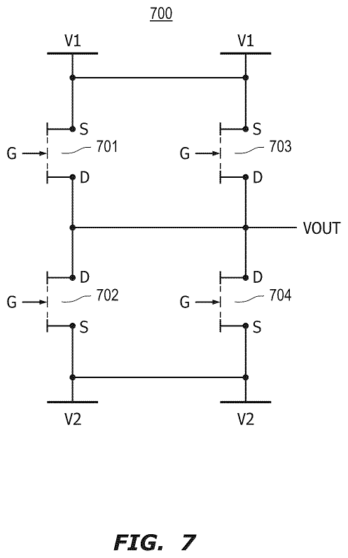

While the circuit 100 may be any circuit in which current flow is useful for operation, in one embodiment that will be described in detail below with respect to FIG. 6, the circuit 100 forms part of a buck converter, boost converter or any other circuit that includes high and low voltage supplies. FIG. 7 shows a second example in which the circuit forms part of a bi-directional switch. However, the applications of FIGS. 6 and 7 are mere examples of the enumerable applications in which current flow is used.

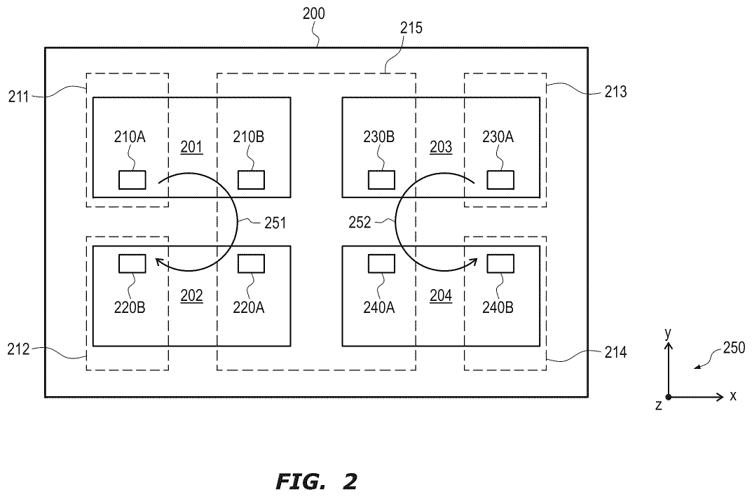

FIG. 2 illustrates an example circuit 200 that represents just one of an enumerable variety of embodiments contemplated as falling within the scope of the broadest principles described herein. The circuit 200 is an integrated circuit that is formed of an epitaxial stack, and that includes four High Electron Mobility Transistors, also called “HEMTs”. Specifically, the circuit includes HEMT 201, HEMT 202, HEMT 203 and HEMT 204, each formed of a different part of the same epitaxial stack. Accordingly, the HEMTs 201 through 204 are monolithically formed on the same integrated circuit.

Each HEMT includes two channel nodes, which could be a drain node or a source node, depending on the application, as will be described by way of example with respect to FIGS. 6 and 7 further below. Specifically, HEMT 201 includes channel nodes 210A and 210B, HEMT 202 includes channel nodes 220A and 220B, HEMT 203 includes channel nodes 230A and 230B, and HEMT 204 includes channel nodes 240A and 240B.

Conductive components reside above (i.e., in the positive z-direction) the HEMTs 201 through 204. Such conductive components are represented with dashed-lined borders. For instance, a first voltage supply node 211 is in conductive contact with the first channel node 210A of the HEMT 201, a second voltage supply node 212 is in conductive contact with the second channel node 220B of the HEMT 202, a third voltage supply node 213 is in conductive contact with the first channel node 230A of the HEMT 203, and a fourth voltage supply node 214 is in conductive contact with the second channel node 240B of the HEMT 204. A switch output node 215 is in conductive contact with the second channel node 210B of HEMT 201, the first channel node 220A of HEMT 202, the second channel node 230B of HEMT 203, and the first channel node 240A of HEMT 204.

The voltage supply nodes 211 through 214 are respectively examples of the voltage supply nodes 111 through 114 of FIG. 1. When both HEMTs 201 and 202 are at least partially on, the HEMTs 201 and 202 are an example of the first current path circuit 101 of FIG. 1. In this case, if the voltage at the first voltage supply node 211 is higher than the voltage at the second voltage supply node 212, current will flow from the first voltage supply node 211, through the first HEMT 201 from its first channel node 210A to its second channel node 210B, through the switch output node 215, through the second HEMT 202 from its first channel node 220A to its second channel node 220B and to the second voltage supply node 212. This represents a clockwise flow of current (as represented by arrow 251) in the current flow plane, which in this case is the x-y plane of the coordinate system 250, which is perpendicular to a direction of epitaxial growth (the positive z-direction in FIG. 2) of the epitaxial stack in which the HEMTs 201 through 204 are formed.

Likewise, when both HEMTs 203 and 204 are at least partially on, the HEMTs 203 and 204 are an example of the second current path circuit 102 of FIG. 1. In this case, if the voltage at the third voltage supply node 213 is higher than the voltage at the fourth voltage supply node 214, current will flow from the third voltage supply node 213, through the third HEMT 203 from its first channel node 230A to its second channel node 230B, through the switch output node 215, through the fourth HEMT 204 from its first channel node 240A to its second channel node 240B and to the fourth voltage supply node 214. This represents a counterclockwise flow of current in the current flow plane as represented by arrow 252.

As with the circuit 100 of FIG. 1, the circuit 200 of FIG. 2 may be any circuit in which current flow is useful for operation. In one embodiment described below with respect to FIG. 6, the circuit 200 forms part of a buck converter, boost converter or any other circuit that includes high and low voltage supplies. FIG. 7 shows a second example in which the circuit 200 forms part of a bi-directional switch. However, the applications of FIGS. 6 and 7 are mere examples of the enumerable applications in which current flow is used. The principles described herein are not limited to what the counterrotating current is used for.

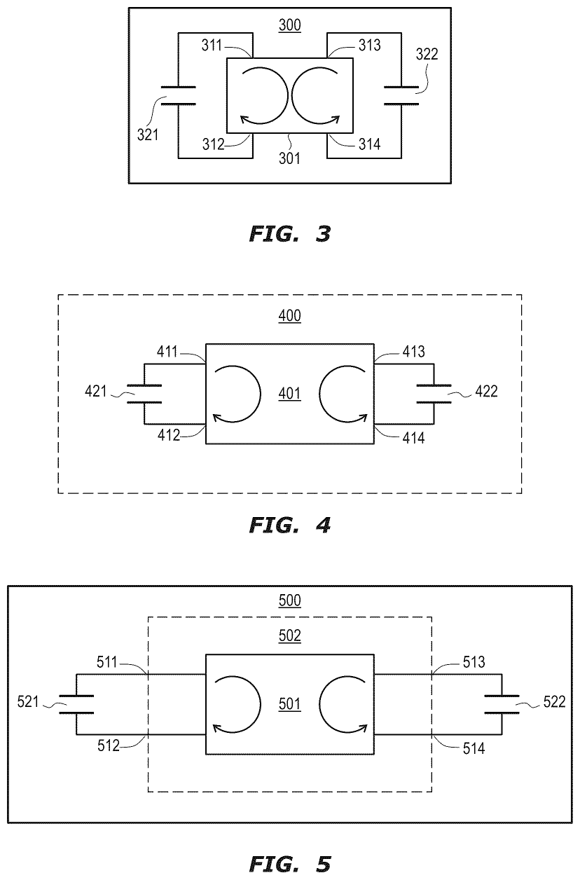

The capacitors 121 and 122 are not shown in FIG. 2 because it is not important where the capacitors 121 and 122 are with respect to the current path circuits, and as previously mentioned, the broadest principles described herein do not require the capacitors 121 and 122 at all. Nevertheless, FIG. 3 illustrates an integrated circuit 300 that includes an instance 301 of the circuit 200 of FIG. 2. That is, the instance 301 includes the four HEMTs 201 through 204 of FIG. 3. In this case, the voltage sources 311 through 314 are examples of the respective voltage supply nodes 211 through 214 of FIG. 2, and the capacitors 321 and 322 are respective examples of the capacitors 121 and 122 of FIG. 1. Here, capacitors 321 and 322 are also formed on the same integrated circuit 300 using the same epitaxial stack as the instance 301 of the circuit 200 that includes the HEMTs. As an example, the capacitors 321 and 322 may each be formed by two conductive layers planar to the x-y plane, and having a dielectric layer therebetween.

As an alternative, FIG. 4 illustrates a package 400 in which an integrated circuit 401 is packaged. Here, the integrated circuit 401 represents an example of the circuit 200 of FIG. 2, which includes the four HEMTs 201 through 204. In this case, the voltage sources 411 through 414 are examples of the respective voltage supply nodes 211 through 214 of FIG. 2, and the capacitors 421 and 422 are respective examples of the capacitors 121 and 122 of FIG. 1. Here, the capacitors 421 and 422 are not within the same integrated circuit 401 as the HEMTs, but are within the same package 400.

As yet another alternative, FIG. 5 illustrates a circuit board 500 in which a package 502 is mounted, where the package 502 contains an integrated circuit 501 that represents an instance of the circuit 200 of FIG. 2. In this case, the voltage sources 511 through 514 are examples of the respective voltage supply nodes 211 through 214 of FIG. 2, and the capacitors 521 and 522 are respective examples of the capacitors 121 and 122 of FIG. 1. Here, the capacitors 521 and 522 are not within the same integrated circuit 501 as the HEMTs, and are also not packaged in the same package 502 with the HEMTs, but are on the same circuit board as the HEMTs. In one example, the current flow plane is the plane of the circuit board, although that is not required.

Again, the circuit 100 of FIG. 1, and the circuit 200 of FIG. 2 may be any circuit in which current flow is useful for operation. As a mere example, FIG. 6 illustrates an example circuit 600 in which there are four HEMTs 601 through 604 that may each be structured as described below for the HEMTs 201 through 204 of FIG. 2. In this case, the drain of each of the HEMTs 601 and 603 is connected to a voltage source VIN, and the source of each of the HEMTs 602 and 604 is connected to ground GND, which is a lower voltage than VIN. The drain of the HEMT 602 is connected to the source of the HEMT 601 and to the switch output node having voltage VOUT. Likewise, the drain of the HEMT 604 is connected to the source of the HEMT 603 and to the switch output node having voltage VOUT. Accordingly, in the embodiment of FIG. 6, the HEMTs 601 and 603 will be referred to as high-side HEMT 601 and high-side HEMT 603. Likewise, the HEMTs 602 and 604 will be referred to as low-side HEMT 602 and low-side HEMT 604.

In this case, if the HEMTs 601 through 604 were each respective instances of the HEMTs 201 through 204 of FIG. 2, the channel nodes 210A and 210B of the HEMT 201 would be the respective drain and source of the HEMT 201, the channel nodes 220A and 220B of the HEMT 202 would be the respective drain and source of the HEMT 202, the channel nodes 230A and 230B of the HEMT 203 would be the respective drain and source of the HEMT 203, and the channel nodes 240A and 240B of the HEMT 204 would be the respective drain and source of the HEMT 204.

In FIG. 6, the circuit 600 regulates a voltage VOUT that is between GND and VIN by controlling the duty cycle of the high-side HEMTs 601 and 603, and the duty cycle of the low-side HEMTs 602 and 604. Most of the time, when the high-side HEMTs 601 and 603 are on, the low-side HEMTs 602 and 604 are off, and vice versa. To obtain a higher output voltage VOUT, the duty cycle of the high-side HEMTs 601 and 603 are increased, and the duty cycle of the low-side HEMTs 602 and 604 is decreased. To obtain a lower output voltage VOUT, the duty cycle of the high-side HEMTs 601 and 603 are decreased, and the duty cycle of the low-side HEMTs 602 and 604 is increased. Of course, in a buck converter, there is an inductor-capacitor network (not shown in FIG. 6) connected to the output switch node to stabilize the output voltage VOUT. That said, the circuit 600 of FIG. 6 may also be implemented within a boost converter or any other circuit that includes high and low voltage supplies.

Since the gate voltage applied to the high-side HEMTs 601 and 603 is the same, with their drains connected to each other and with their sources connected to each other, the high-side HEMTs 601 and 603 behave as a single high-side HEMT (except for the EMI cancellation properties caused during transitions as will shortly be described). Furthermore, since the gate voltage applied to the low-side HEMTs 602 and 604 is the same, with their drains connected to each other and with their sources connected to each other, the low-side HEMTs 602 and 604 behave as a single low-side HEMT (except for the EMI cancellation properties).

During a transition period, the high-side HEMTs 601 and 603 are being turned on whilst the low-side HEMTs 602 and 604 are being turned off, or the high-side HEMTs 601 and 603 are being turned off whilst the low-side HEMTs 602 and 604 are being turned on. In the brief transition period, there will be a brief period in which current flows from VCC1 to GND1 through the HEMTs 601 and 602, and current flows from VCC2 to GND2 through the HEMTs 603 and 604. Furthermore, during this transition period, the change in current and voltage at the various nodes of the circuit may be quite rapid, resulting in high frequency power changes, thereby causing EMI to be emitted in high frequency ranges.

However, in accordance with the principles described herein, the current flow through HEMTs 601 and 602 is one current path having one rotational direction in the current flow plane (referring again to FIGS. 1 and 2), and the current flow through HEMTs 603 and 604 is another current path having an opposite rotational direction. Thus, the high frequency emissions will largely be cancelled. Thus, the principles described herein may be applied to a buck converter, boost converter, or any other circuit that has a high and low voltage supply, to limit EMI emissions during the transition phase. Accordingly, the circuit 600 may form part of a buck converter, boost converter, or any other circuit that has low EMI emissions.

FIG. 7 shows a second example circuit 700 in which there are four HEMTs 701 through 704 that may each be structured as described below for the HEMTs 201 through 204 of FIG. 2. Unlike in FIG. 6, FIG. 7 shows the HEMTs in a common drain configuration, and that may behave as a bi-directional switch, except for EMI cancellation properties. In this case, the source of each of the HEMTs 701 and 703 is connected to a voltage source V1, and the source of each of the HEMTs 702 and 704 is connected to another voltage source V2.

When the bi-directional switch is on, if voltage V1 is higher than voltage V2, current flows downwards in FIG. 7 from V1 in a first current path through HEMTs 701 and 702 and to voltage V2, and current flows downward in a second current path through HEMTs 703 and 704 and to a voltage V2. In this case, if the HEMTs 701 through 704 are instances of the HEMTs 201 through 204 of FIG. 2, the first current path would be clockwise, and the second current path would be counterclockwise. On the other hand, when the bi-directional switch is on, and if the voltage V1 is lower than the voltage V2, current flows upwards from V2 in a first current path through HEMTs 702 and 701 and to voltage V1, and current flows upwards in a second current path through HEMTs 704 and 703 and to a voltage V2. In this case, if the HEMTs 701 through 704 are instances of the HEMTs 201 through 204 of FIG. 2, the first current path would be counterclockwise, and the second current path would be clockwise. In either case, EMI would be largely cancelled.

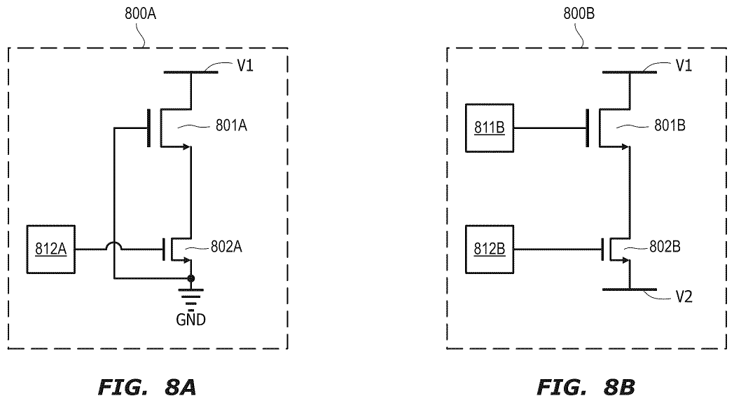

The HEMTs described above may each be enhancement mode (normally off) HEMTs or depletion mode (normally on) HEMTs. However, if normally off HEMT behavior is desired, a normally on HEMT may be used with another low voltage transistor to perform normally off behavior. For example, FIG. 8A illustrates a circuit 800A that includes a normally on HEMT 801A and a low voltage transistor 802A (such as, but not limited to, a MOSFET) connected in series between a high voltage source V1 and ground. The gate of the normally on HEMT 801A is connected to the source of the low voltage transistor 802A, and only the gate of the low voltage transistor is active driven (e.g., by driver 812A) to control the flow of current from the high voltage source V1 to ground. This configuration is referred to herein is a “cascode configuration of an enhancement mode HEMT”.

FIG. 8B illustrates another circuit 800B in which a normally off behavior is emulated by a normally on HEMT 801B and a low voltage transistor 802B connected in series between a first voltage source V1 and a second voltage source V2. Here, the HEMT 801B and the low voltage transistor 802B are both actively driven. That is, the HEMT 801B is driven by driver 811B, and the low voltage transistor 802B is driven by the driver 812B. This configuration is referred to herein is a “direct drive configuration of an enhancement mode HEMT”.

Thus, the circuit 800A or the circuit 800B may be used for any of the HEMTs described above with respect to FIGS. 2 through 6. If the low voltage transistor is formed on the same integrated circuit as the HEMT, then the circuit 800A or the circuit 800B may be used as a HEMT in the integrated circuit 300 of FIG. 3. However, if the low voltage transistor is rather a silicon MOSFET, then the silicon MOSFET may either be co-packaged with the HEMT (e.g., within the package 400 of FIG. 4, but not on the integrated circuit 401), or may be on the same board (e.g., board 500) as the HEMTs.

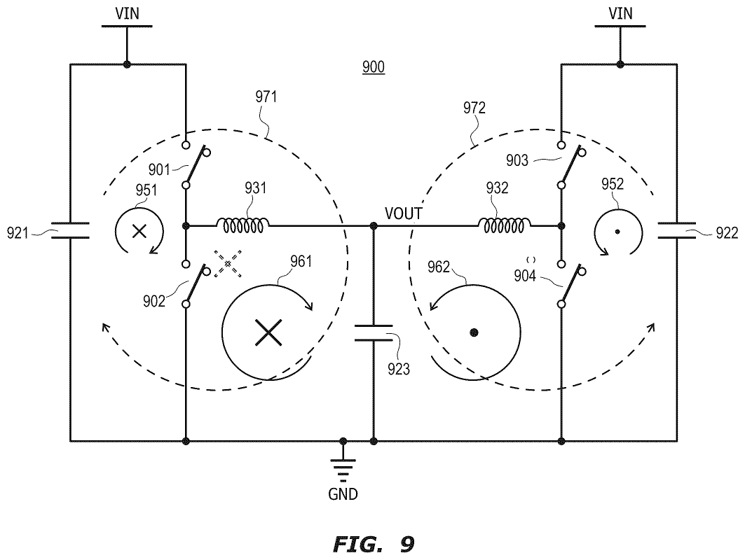

FIG. 9 illustrates an embodiment of a buck converter circuit 900 that is an extension of the circuit 600 of FIG. 6. That is transistors 901 through 904 may be instances of respective HEMTs 601 through 604 of FIG. 4. Alternatively, as just described, the transistors 901 through 904 may be any of the circuits 800A or 800B. Furthermore capacitor 921 is also shown allowing for a first current path 951 (shown as having clockwise rotation in FIG. 9), and capacitor 922 is also shown allowing for the second current path 952 (shown as having a counterclockwise rotation in FIG. 9). These current paths are active during the brief period in which the buck converter circuit 900 is transitioning on and off, thereby generating high frequency EMI that are at least partially cancelled out by the counter-rotational nature of the two current paths 951 and 952.

However, as previously mentioned, a buck converter includes an inductor-capacitor network that allows for a stable output voltage VOUT to be produced. This network is used to provide another instance of counter-rotational current flow that occurs at lower frequencies.

Specifically, an inductor 931 is coupled between the common node of the transistors 901 and 902 and the output node that carries the voltage VOUT. An output capacitor 923 is connected between the output node that carries the voltage VOUT and the ground node that carries the voltage GND. This results in clockwise rotational current path 961 that has lower frequency components but still could be considered EMI for many surrounding circuits. The larger path represented by the combination of current paths 951 and 961 is represented by current path 971.

In addition, the inductor 932 is coupled between the common node of the transistors 903 and 904 and the output node that carries the voltage VOUT. Again, the output capacitor 923 is connected between the output node that carries the voltage VOUT and the ground node that carries the voltage GND. This results in counter-clockwise rotational current path 962 that has lower frequency components but still could be considered EMI for many surrounding circuits. However, the EMI emitted by the rotational paths 961 and 962 largely mirror one another, and thus the resulting EMI is largely cancelled. The larger path represented by the combination of current paths 952 and 962 is represented by current path 972.

As the inductors 931 and 932 are larger components that are difficult to effectively manufacture on chip, the inductors 931 and 932 may be more effectively implemented on a circuit board in which the inductors 931 and 932 are mounted. Furthermore, the capacitor 923 is likely to be larger than the capacitors 921 and 922, because the capacitor 923 is to have sufficient capacity to stably maintain the voltage VOUT, and have low enough impedance to maintain the flows of the current paths 961 and 962 despite the current paths 961 and 962 having lower frequencies than that of the current paths 951 and 952. Thus, the capacitor 923 may be implemented on a circuit board.

Accordingly, what has been described is a circuit that includes two current path circuits—a first current path circuit and a second current path circuit in which current flow is in opposite rotational directions in a current flow plane. If a same differential voltage is applied across the first current path circuit and the second current path circuit, this will induce relative counter rotational current in each current path circuit. This is true even if the first voltage and/or second voltage are changing. Accordingly, the counterflows at least partially cancel out electromagnetic interference across a range of frequencies.

### Literal Claim Support Section

Clause 1. A circuit comprising: a first current path circuit having a first voltage supply node and a second voltage supply node, the first current path circuit structured such that when current flows from the first voltage supply node to the second voltage supply node, current flow through the first current path circuit is in a first rotational direction in a current flow plane; and a second current path circuit having a third voltage supply node and a fourth voltage supply node, the second current path circuit structured to such that when current flows from the third voltage supply node to the fourth voltage supply node, current flow through the second current path circuit is in a second rotational direction in the current flow plane, the second rotational direction being opposite the first rotational direction in the current flow plane.

Clause 2. The circuit in accordance with Clause 1, the circuit structured such that if a same first voltage is applied to the first voltage supply node and the third voltage supply node, and if a same second voltage is applied to the second supply node and the fourth supply node, current would flow in different rotational directions in the first current path circuit as compared to the second current path circuit thereby attenuating electromagnetic interference.

Clause 3. The circuit of Clause 1, the first current path circuit comprising a first High Electron Mobility Transistor (HEMT) formed of part of an epitaxial stack, and a second HEMT formed of part of the epitaxial stack, the current flow plane being perpendicular to a direction of epitaxial growth of the epitaxial stack, the first HEMT having a first channel node connected toa the first voltage supply node and a second channel node connected to a switch output node of the circuit, the second HEMT having a first channel node connected to the switch output node of the circuit and a second channel node connected to the second voltage supply node, and the first current path circuit comprising a first High Electron Mobility Transistor (HEMT) formed of part of an epitaxial stack, and a second HEMT formed of part of the epitaxial stack, the current flow plane being perpendicular to a direction of epitaxial growth of the epitaxial stack, the first HEMT having a first channel node connected to the first voltage supply node and a second channel node connected to a switch output node of the circuit, the second HEMT having a first channel node connected to the switch output node of the circuit and a second channel node connected to the second voltage supply node, and the second current path circuit comprising a third HEMT formed of part of the epitaxial stack, and a fourth HEMT formed of part of the epitaxial stack, the third HEMT having a first channel node connected to the third voltage supply node and a second channel node that is connected to the switch output node of the circuit, the second HEMT having a first channel node connected to the switch output node of the circuit and a second channel node connected to the fourth voltage supply node.

Clause 4. The circuit of Clause 3, the first channel node of the first HEMT being a drain node of the first HEMT, the second channel node of the first HEMT being a source node of the first HEMT, the first channel node of the second HEMT being a drain node of the second HEMT, the second channel node of the second HEMT being a source node of the second HEMT, and the first channel node of the third HEMT being a drain node of the third HEMT, the second channel node of the third HEMT being a source node of the third HEMT, the first channel node of the fourth HEMT being a drain node of the fourth HEMT, the second channel node of the fourth HEMT being a source node of the fourth HEMT.

Clause 5. The circuit of Clause 4, the circuit being a buck converter circuit or a boost converter circuit such that if a same first voltage is applied to the first voltage supply node and the second voltage supply node, a same second voltage is applied to the third supply node and the fourth supply node, a same first gate control signal is applied to the first HEMT and the third HEMT, and a second gate control signal is applied to the second HEMT and the fourth HEMT, the circuit outputs an output signal on the switch output node.

Clause 6. The circuit of Clause 3, the circuit being a bi-directional switch, the first channel node of the first HEMT being a source node of the first HEMT, the second channel node of the first HEMT being a drain node of the first HEMT, the first channel node of the second HEMT being a drain node of the second HEMT, the second channel node of the second HEMT being a source node of the second HEMT, and the first channel node of the third HEMT being a source node of the third HEMT, the second channel node of the third HEMT being a drain node of the third HEMT, the first channel node of the fourth HEMT being a drain node of the fourth HEMT, the second channel node of the fourth HEMT being a source node of the fourth HEMT.

Clause 7. A circuit comprising: a first current path circuit having a first voltage supply node, a second voltage supply node, a first High-Electron Mobility Transistor (HEMT) formed of part of an epitaxial stack, and a second HEMT formed of part of the epitaxial stack, a current flow plane being perpendicular to a direction of epitaxial growth of the epitaxial stack, the first HEMT having a first channel node connected to the first voltage supply node and a second channel node connected to a switch output node of the circuit, the second HEMT having a first channel node connected to the switch output node of the circuit and a second channel node connected to the second voltage supply node, the first current path circuit structured such that when current flows from the first voltage supply node through the first HEMT, the second HEMT, and to the second voltage supply node, the current flows in a first rotational direction along a first flow path in the current flow plane; and a second current path circuit having a third voltage supply node, a fourth voltage supply node, a third HEMT formed of part of an epitaxial stack, and a fourth HEMT formed of part of the epitaxial stack, the third HEMT having a first channel node connected to the third voltage supply node and a second channel node that is connected to the switch output node of the circuit, the fourth HEMT having a first channel node connected to the switch output node of the circuit and a second channel node connected to the fourth voltage supply node, the second current path circuit structured such that when current flows from the third voltage supply node through the third HEMT, the fourth HEMT, and to the fourth voltage supply node, the current flows in a second flow path in a second rotational direction in the current flow plane, the second rotational direction being opposite the first rotational direction in the current flow plane.

Clause 8. The circuit of Clause 7, the first HEMT, the second HEMT, the third HEMT, and the fourth HEMT formed on an integrated circuit that includes the epitaxial stack.

Clause 9. The circuit of Clause 8, the first circuit path further comprising: a first capacitor having a first terminal connected to the first voltage supply node, and a second terminal connected to the second voltage supply node; and a second capacitor having a first terminal connected to the third voltage supply node, and a second terminal connected to the fourth voltage supply node.

Clause 10. The circuit of Clause 9, the first capacitor and the second capacitor also formed on the integrated circuit.

Clause 11. The circuit of Clause 9, further comprising a package that contains the integrated circuit.

Clause 12. The circuit of Clause 11, the package further containing the first capacitor and the second capacitor that are each not formed on the integrated circuit.

Clause 13. The circuit of Clause 11, further comprising a circuit board that is connected to the package.

Clause 14. The circuit of Clause 13, at least one of the first HEMT, the second HEMT, the third HEMT, or the fourth HEMT being in cascode configuration with a low voltage transistor, the low voltage transistor being outside of the package and on the circuit board.

Clause 15. The circuit of Clause 13, at least one of the first HEMT, the second HEMT, the third HEMT, or the fourth HEMT being in cascode configuration with a low voltage transistor, the low voltage transistor being outside of the package and on the circuit board.

Clause 16. The circuit of Clause 13, the first capacitor and the second capacitor being on the circuit board outside of the package.

Clause 17. The circuit of Clause 7, the first flow path circuit and the second flow path circuit forming a buck converter.

Clause 18. The circuit of Clause 7, the first flow path circuit and the second flow path circuit forming a bi-directional switch.

Clause 19. A circuit board comprising: a first current path circuit having a first voltage supply node and a second voltage supply node, the first current path circuit structured such that when current flows from first voltage supply node to the second voltage supply node, current flow through the first current path circuit is in a first rotational direction in a current flow plane that is perpendicular to a plane in which the circuit board extends; and a second current path circuit having a third voltage supply node and a fourth voltage supply node, the second current path circuit structured to such that when current flows from the third voltage supply node to the fourth voltage supply node, current flow through the first current path circuit is in a second rotational direction in the current flow plane, the second rotational direction being opposite the first rotational direction in the current flow plane.

Clause 20. The circuit board of Clause 17, further comprising: a first capacitor mounted to a board of the circuit board, and having a first terminal connected to the first voltage supply node, and a second terminal connected to the second voltage supply node, the first capacitor connected to the circuit board; and a second capacitor mounted to the board, and having a first terminal connected to the third voltage supply node, and a second terminal connected to the fourth voltage supply node.

Although the subject matter has been described in language specific to structural features and/or methodological acts, it is to be understood that the subject matter defined in the appended claims is not necessarily limited to the described features or acts described above, or the order of the acts described above. Rather, the described features and acts are disclosed as example forms of implementing the claims.

The present disclosure may be embodied in other specific forms without departing from its essential characteristics. The described embodiments are to be considered in all respects only as illustrative and not restrictive. All changes which come within the meaning and range of equivalency of the claims are to be embraced within their scope.

When introducing elements in the appended claims, the articles “a,” “an,” “the,” and “said” are intended to mean there are one or more of the elements. The terms “comprising,” “including,” and “having” are intended to be inclusive and mean that there may be additional elements other than the listed elements.

What is claimed is:

1. A circuit comprising:
a first current path circuit having a first voltage supply node and a second voltage supply node, the first current path circuit structured such that when current flows from the first voltage supply node to the second voltage supply node, current flow through the first current path circuit is in a first rotational direction in a current flow plane; and
a second current path circuit having a third voltage supply node and a fourth voltage supply node, the second current path circuit structured to such that when current flows from the third voltage supply node to the fourth voltage supply node, current flow through the second current path circuit is in a second rotational direction in the current flow plane, the second rotational direction being opposite the first rotational direction in the current flow plane.

2. The circuit in accordance with claim 1, the circuit structured such that if a same first voltage is applied to the first voltage supply node and the third voltage supply node, and if a same second voltage is applied to the second supply node and the fourth supply node, current would flow in different rotational directions in the first current path circuit as compared to the second current path circuit thereby attenuating electromagnetic interference.

3. The circuit of claim 1,
the first current path circuit comprising a first High Electron Mobility Transistor (HEMT) formed of part of an epitaxial stack, and a second HEMT formed of part of the epitaxial stack, the current flow plane being perpendicular to a direction of epitaxial growth of the epitaxial stack, the first HEMT having a first channel node connected toa the first voltage supply node and a second channel node connected to a switch output node of the circuit, the second HEMT having a first channel node connected to the switch output node of the circuit and a second channel node connected to the second voltage supply node, and the first current path circuit comprising a first High Electron Mobility Transistor (HEMT) formed of part of an epitaxial stack, and a second HEMT formed of part of the epitaxial stack, the current flow plane being perpendicular to a direction of epitaxial growth of the epitaxial stack, the first HEMT having a first channel node connected to the first voltage supply node and a second channel node connected to a switch output node of the circuit, the second HEMT having a first channel node connected to the switch output node of the circuit and a second channel node connected to the second voltage supply node, and
the second current path circuit comprising a third HEMT formed of part of the epitaxial stack, and a fourth HEMT formed of part of the epitaxial stack, the third HEMT having a first channel node connected to the third voltage supply node and a second channel node that is connected to the switch output node of the circuit, the second HEMT having a first channel node connected to the switch output node of the circuit and a second channel node connected to the fourth voltage supply node.

4. The circuit of claim 3,
the first channel node of the first HEMT being a drain node of the first HEMT, the second channel node of the first HEMT being a source node of the first HEMT, the first channel node of the second HEMT being a drain node of the second HEMT, the second channel node of the second HEMT being a source node of the second HEMT, and
the first channel node of the third HEMT being a drain node of the third HEMT, the second channel node of the third HEMT being a source node of the third HEMT, the first channel node of the fourth HEMT being a drain node of the fourth HEMT, the second channel node of the fourth HEMT being a source node of the fourth HEMT.

5. The circuit of claim 4, the circuit being a buck converter circuit or a boost converter circuit such that if a same first voltage is applied to the first voltage supply node and the second voltage supply node, a same second voltage is applied to the third supply node and the fourth supply node, a same first gate control signal is applied to the first HEMT and the third HEMT, and a second gate control signal is applied to the second HEMT and the fourth HEMT, the circuit outputs an output signal on the switch output node.

6. The circuit of claim 3, the circuit being a bi-directional switch,
the first channel node of the first HEMT being a source node of the first HEMT, the second channel node of the first HEMT being a drain node of the first HEMT, the first channel node of the second HEMT being a drain node of the second HEMT, the second channel node of the second HEMT being a source node of the second HEMT, and
the first channel node of the third HEMT being a source node of the third HEMT, the second channel node of the third HEMT being a drain node of the third HEMT, the first channel node of the fourth HEMT being a drain node of the fourth HEMT, the second channel node of the fourth HEMT being a source node of the fourth HEMT.

7. A circuit comprising:
a first current path circuit having a first voltage supply node, a second voltage supply node, a first High-Electron Mobility Transistor (HEMT) formed of part of an epitaxial stack, and a second HEMT formed of part of the epitaxial stack, a current flow plane being perpendicular to a direction of epitaxial growth of the epitaxial stack, the first HEMT having a first channel node connected to the first voltage supply node and a second channel node connected to a switch output node of the circuit, the second HEMT having a first channel node connected to the switch output node of the circuit and a second channel node connected to the second voltage supply node, the first current path circuit structured such that when current flows from the first voltage supply node through the first HEMT, the second HEMT, and to the second voltage supply node, the current flows in a first rotational direction along a first flow path in the current flow plane; and
a second current path circuit having a third voltage supply node, a fourth voltage supply node, a third HEMT formed of part of an epitaxial stack, and a fourth HEMT formed of part of the epitaxial stack, the third HEMT having a first channel node connected to the third voltage supply node and a second channel node that is connected to the switch output node of the circuit, the fourth HEMT having a first channel node connected to the switch output node of the circuit and a second channel node connected to the fourth voltage supply node, the second current path circuit structured such that when current flows from the third voltage supply node through the third HEMT, the fourth HEMT, and to the fourth voltage supply node, the current flows in a second flow path in a second rotational direction in the current flow plane, the second rotational direction being opposite the first rotational direction in the current flow plane.

8. The circuit of claim 7, the first HEMT, the second HEMT, the third HEMT, and the fourth HEMT formed on an integrated circuit that includes the epitaxial stack.

9. The circuit of claim 8, the first circuit path further comprising:
a first capacitor having a first terminal connected to the first voltage supply node, and a second terminal connected to the second voltage supply node; and
a second capacitor having a first terminal connected to the third voltage supply node, and a second terminal connected to the fourth voltage supply node.

10. The circuit of claim 9, the first capacitor and the second capacitor also formed on the integrated circuit.

11. The circuit of claim 9, further comprising a package that contains the integrated circuit.

12. The circuit of claim 11, the package further containing the first capacitor and the second capacitor that are each not formed on the integrated circuit.

13. The circuit of claim 11, further comprising a circuit board that is connected to the package.

14. The circuit of claim 13, at least one of the first HEMT, the second HEMT, the third HEMT, or the fourth HEMT being in cascode configuration with a low voltage transistor, the low voltage transistor being outside of the package and on the circuit board.

15. The circuit of claim 13, at least one of the first HEMT, the second HEMT, the third HEMT, or the fourth HEMT being in cascode configuration with a low voltage transistor, the low voltage transistor being outside of the package and on the circuit board.

16. The circuit of claim 13, the first capacitor and the second capacitor being on the circuit board outside of the package.

17. The circuit of claim 7, the first flow path circuit and the second flow path circuit forming a buck converter.

18. The circuit of claim 7, the first flow path circuit and the second flow path circuit forming a bi-directional switch.

19. A circuit board comprising:
a first current path circuit having a first voltage supply node and a second voltage supply node, the first current path circuit structured such that when current flows from first voltage supply node to the second voltage supply node, current flow through the first current path circuit is in a first rotational direction in a current flow plane that is perpendicular to a plane in which the circuit board extends; and
a second current path circuit having a third voltage supply node and a fourth voltage supply node, the second current path circuit structured to such that when current flows from the third voltage supply node to the fourth voltage supply node, current flow through the first current path circuit is in a second rotational direction in the current flow plane, the second rotational direction being opposite the first rotational direction in the current flow plane.

20. The circuit board of claim 17, further comprising:
a first capacitor mounted to a board of the circuit board, and having a first terminal connected to the first voltage supply node, and a second terminal connected to the second voltage supply node, the first capacitor connected to the circuit board; and
a second capacitor mounted to the board, and having a first terminal connected to the third voltage supply node, and a second terminal connected to the fourth voltage supply node.
